(19) United States
(12) Patent Application Publication
(10) Pub. No.: US 2025/0055668 A1
(43) Pub. Date: Feb. 13, 2025

(54) Physical layer syntonization using digitally controlled oscillator

(71) Applicant: Mellanox Technologies, Ltd., Yokneam (IL)

(72) Inventors: Natan Manevich, Nesher (IL); Dotan David Levi, Kiryat Motzkin (IL); Arnon Sattinger, Zichron Yaakov (IL); Wojciech Wasko, Mlynek (PL); Maciej Machnikowski, Reda (PL); Doron Fael, Zichron Yaakov (IL); Ofir Sadeh, Shoham (IL); Jonathan Oliel, Ramat Gan (IL)

(21) Appl. No.: 18/448,936

(22) Filed: Aug. 13, 2023

(51) Int. Cl. H04L 7/033; H03L 7/099; H04L 7/10

(52) U.S. Cl. CPC H04L 7/033; H03L 7/0992; H04L 7/10

(57) ABSTRACT

In one embodiment, a system includes a digitally controlled oscillator (DCO) to generate a local clock having a local clock frequency, and clock synchronization circuitry to receive from a device a signal indicative of a remote clock frequency, compare measures of the remote clock frequency and the local clock frequency; generate a digital control command based on the comparison; and provide the digital control command to the DCO, wherein the DCO is to adjust the local clock frequency responsively to the digital control command.

### FIELD OF THE INVENTION

The present invention relates to computer systems, and in particular, but not exclusively to, clock syntonization.

### BACKGROUND

Clock synchronization among network devices is used in many network applications. One application of using a synchronized clock value is for measuring one-way latency from one device to another device. If the clocks are not synchronized the resulting one-way latency measurement will be inaccurate.

Synchronization is typically achieved by syntonization, in which the clock frequency of two devices is aligned, and aligning the phase between the two devices.

For Ethernet, there are two complementary methods to achieve synchronization. One is Synchronous Ethernet (SyncE), which is a physical-layer protocol which achieves syntonization based on the receive/transmit symbol rate. SyncE is an International Telecommunication Union Telecommunication (ITU-T) Standardization Sector standard for computer networking that facilitates the transference of clock signals over the Ethernet physical layer. In particular, SyncE enables clock syntonization inside a network with respect to a master clock.

The other is Precision Time Protocol (PTP), which is a packet-based protocol that may be used with SyncE to align offset (e.g., in Coordinated Universal Time (UTC) format) and phase between two clocks. It should be noted that PTP may be used alone over Ethernet (without SyncE), but this is typically used for lower accuracy use cases. PTP is used to synchronize clocks throughout a computer network, and is considered to be the de facto standard for this purpose.

Time, clock, and frequency synchronization are crucial in some modern computer network applications. It enables 5G and 6G networks, and is proven to enhance the performance of data center workloads.

### SUMMARY

There is provided in accordance with an embodiment of the present disclosure, a system, including a digitally controlled oscillator (DCO) to generate a local clock having a local clock frequency, and clock synchronization circuitry to receive from a device a signal indicative of a remote clock frequency, compare measures of the remote clock frequency and the local clock frequency, generate a digital control command based on the comparison, and provide the digital control command to the DCO, wherein the DCO is to adjust the local clock frequency responsively to the digital control command.

Further in accordance with an embodiment of the present disclosure digital control command indicates a new clock frequency to which to change the local clock frequency by the DCO.

Still further in accordance with an embodiment of the present disclosure digital control command indicates a frequency adjustment to be made by the DCO to the local clock frequency.

Additionally in accordance with an embodiment of the present disclosure, the system includes a network interface to receive the signal including first packets from the device over a network and transmit a signal including second packets over the network, the clock synchronization circuitry is to compare a symbol rate of the received signal to a symbol rate of the transmitted signal to provide the comparison of the remote clock frequency and the local clock frequency.

Moreover, in accordance with an embodiment of the present disclosure, the system includes multiple chips, wherein the network interface and the clock synchronization circuitry are distributed among the multiple chips.

Further in accordance with an embodiment of the present disclosure the clock synchronization circuitry includes at least one counter in which the clock synchronization circuitry is to count symbols of the received signal and the transmitted signal in a time window, the clock synchronization circuitry is to run firmware to compute the comparison of the remote clock frequency and the local clock frequency based on at least one symbol count of the at least one counter.

Still further in accordance with an embodiment of the present disclosure, the system includes a clock input port to receive the signal from the device via a clock connection, the clock synchronization circuitry is configured to compare features of the received signal and the local clock to provide the comparison of the remote clock frequency and the local clock frequency.

Additionally in accordance with an embodiment of the present disclosure the clock synchronization circuitry includes clock chaining logic which includes at least one counter in which the clock chaining logic is to count the features of the received signal and the local clock in a time window, the clock synchronization circuitry being to run firmware to compute the comparison of the remote clock frequency and the local clock frequency based on at least one count value of the at least one counter.

Moreover, in accordance with an embodiment of the present disclosure, the system includes a clock output port to provide a clock synchronization signal to another device via another clock connection.

Further in accordance with an embodiment of the present disclosure the clock chaining logic is to proportionally change a frequency of the local clock to yield the clock synchronization signal, and provide the clock synchronization signal to the clock output port for output to the other device via the other clock connection.

Still further in accordance with an embodiment of the present disclosure clock synchronization circuitry is to run firmware to compute the comparison of the remote clock frequency and the local clock frequency.

Additionally in accordance with an embodiment of the present disclosure, the system includes a hardware clock to maintain a time-of-day value advancing at a frequency proportional to the local clock frequency of the local clock output by the DCO, wherein the DCO is connected to the hardware clock and is to output the local clock towards the hardware clock.

Moreover, in accordance with an embodiment of the present disclosure, the system includes a network interface including ports to send packets over a network at a symbol rate based on a frequency proportional to the local clock frequency, wherein DCO is connected to the network interface and is to output the local clock towards the network interface.

There is also provided in accordance with another embodiment of the present disclosure, a method, including generating a local clock having a local clock frequency with a digitally controlled oscillator (DCO), receiving from a device a signal indicative of a remote clock frequency, comparing measures of the remote clock frequency and the local clock frequency, generating a digital control command based on the comparison, and provide the digital control command to the DCO, and adjusting the local clock frequency by the DCO responsively to the digital control command.

Further in accordance with an embodiment of the present disclosure digital control command indicates a new clock frequency to which to change the local clock frequency by the DCO.

Still further in accordance with an embodiment of the present disclosure digital control command indicates a frequency adjustment to be made by the DCO to the local clock frequency.

Additionally in accordance with an embodiment of the present disclosure the receiving includes receiving the signal including first packets from the device over a network, the method further including transmitting a signal including second packets over the network, the comparing includes comparing a symbol rate of the received signal to a symbol rate of the transmitted signal to provide the comparison of the remote clock frequency and the local clock frequency.

Moreover, in accordance with an embodiment of the present disclosure, the method includes counting symbols of the received signal and the transmitted signal in a time window using at least one counter, and running firmware to compute the comparison of the remote clock frequency and the local clock frequency based on at least one symbol count of the at least one counter.

Further in accordance with an embodiment of the present disclosure the receiving includes receiving the signal from the device via a clock connection, and the comparing includes comparing features of the received signal and the local clock to provide the comparison of the remote clock frequency and the local clock frequency.

Still further in accordance with an embodiment of the present disclosure, the method includes counting the features of the received signal and the local clock in a time window using at least one counter, and running firmware to compute the comparison of the remote clock frequency and the local clock frequency based on at least one count value of the at least one counter.

Additionally in accordance with an embodiment of the present disclosure, the method includes providing a clock synchronization signal to another device via another clock connection.

Moreover, in accordance with an embodiment of the present disclosure, the method includes proportionally changing a frequency of the local clock to yield the clock synchronization signal.

Further in accordance with an embodiment of the present disclosure, the method includes running firmware to compute the comparison of the remote clock frequency and the local clock frequency.

Still further in accordance with an embodiment of the present disclosure, the method includes maintaining a time-of-day value advancing at a frequency proportional to the local clock frequency of the local clock output by the DCO.

Additionally in accordance with an embodiment of the present disclosure, the method includes sending packets over a network at a symbol rate based on a frequency proportional to the local clock frequency of the local clock output by the DCO.

### BRIEF DESCRIPTION OF THE DRAWINGS

The present invention will be understood from the following detailed description, taken in conjunction with the drawings in which:

FIG. 1 is a block diagram view of a clock synchronization system constructed and operative in accordance with an embodiment of the present invention;

FIG. 2 is a flowchart including steps in a method of operation of the system of FIG. 1 including synchronization to a remote clock frequency received over a network or other high speed communication link; and

FIG. 3 is a flowchart including steps in a method of operation of the system of FIG. 1 including synchronization to a remote clock frequency received from a chained device.

### DESCRIPTION OF EXAMPLE EMBODIMENTS

### Overview

A local device may transmit data including symbols to a remote device at a rate equal to, or proportional to, its local clock frequency. The local device may also receive data including symbols from the remote device at a rate equal to, or proportional to, the clock frequency of the remote device. Therefore, if the remote device is a master clock for the local device, then the local device may syntonize to the master clock by determining if its local clock is faster or slower than the master clock based on a difference between its send symbol rate and receive symbol rate from the remote device and adjust the frequency of its local clock accordingly.

There are many challenges to overcome when designing a local clock which needs to be syntonized with a master clock. Some clocks may have low phase noise but have poor drift stability over time. Other clocks, such as temperature or oven compensated clocks may have good drift stability but suffer from phase noise issues.

Embodiments of the present invention address at least some of the above challenges by providing a local clock with low phase noise and good drift stability using a digitally controlled oscillator (DCO) which is controlled by a digital control command. The DCO may include a temperature compensated oscillator and generate an output frequency of around 156.25 MHz. Clock synchronization circuitry tracks the difference between the frequency of the local clock and a remote master clock (e.g., using one or more counters to count received and transmitted symbols in a time window) and instructs the DCO, using a digital control command, to increase or decrease the rate of the local clock based on the tracked difference. The local clock is then adjusted (iteratively) until the local clock is synchronized with the remote master clock.

In some embodiments, firmware running on a firmware controller may read the counter value(s) in order to determine whether the local clock is faster or slower than the remote master clock. The firmware then generates the digital control command, which is then provided to the DCO.

In some embodiments, the remote master clock may be received from a link partner over a network. In some embodiments, clock synchronization is implemented with a network device including a network interface controller (NIC) application specific integrated circuit (ASIC). The ASIC includes ports, clock synchronization circuitry including a firmware controller, and a hardware clock. The ASIC is mounted on a printed circuit board (PCB), which also includes the DCO. The firmware controller provides digital control commands to the DCO via a digital control channel connecting the ASIC with the DCO. The DCO then provides the local clock to the ports and the hardware clock on the ASIC via another connection from the DCO to the ASIC. In some embodiments, the firmware controller may be included in an integrated circuit, which is external to the NIC ASIC.

In some cases, the identity of the master clock may not be known and only becomes known after time. Therefore, the receive symbol rates of all the ports may be tracked by the clock synchronization circuitry (e.g., using multiple counters) and when the identity of the master clock is known the firmware determines whether the local clock is faster or slower than the remote master clock (e.g., based on using the value of the relevant counter of the relevant port receiving the remote master clock).

In some embodiments, the network device may include multiple NIC ASICs, with each ASIC including ports and clock synchronization circuitry. The ASICs are mounted on a PCB with the DCO and firmware controller. The firmware controller identifies the port receiving the remote master clock from among the ports on the different ASICs and determines whether the local clock is faster or slower than the remote master clock and generates a digital control command and provides the digital control command to the DCO to adjust the frequency of the local clock. The local clock is provided to the ports on each of the ASICs and to the hardware clocks on each of the ASICs.

In some embodiments, the remote master clock may be received from a device connected via a clock connection, e.g., a clock cable or a printed circuit board (PCB) trace. Similarly, a clock synchronization signal based on the local clock may be generated and provided to another device connected to the local device via another clock connection, e.g., a clock cable or a PCB trace.

### System Description

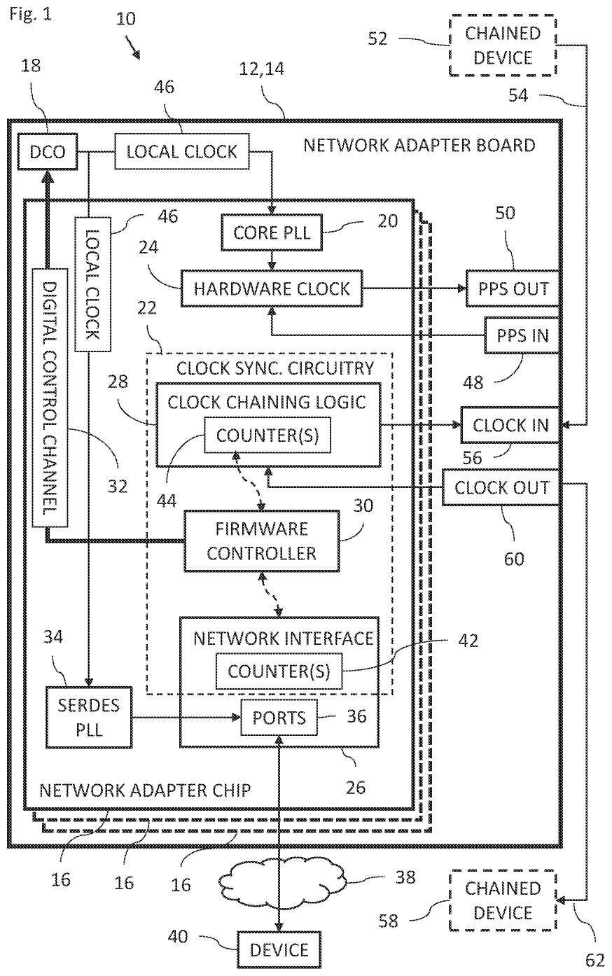

Reference is now made to FIG. 1, which is a block diagram view of a clock synchronization system 10 constructed and operative in accordance with an embodiment of the present invention.

The clock synchronization system 10 includes a device 12. In the example of FIG. 1, the device 12 is a network device including a network adapter board 14 (e.g., PCB) and one or more network adapter chips 16, e.g., NIC ASICs mounted on the network adapter board 14. The device 12 may be implemented as any suitable processing device, for example, a device including a CPU and/or a GPU.

The device 12 includes a digitally controller oscillator (DCO) 18 mounted on the network adapter board 14. The DCO 18 is configured to generate a local clock 46 having a local clock frequency. SiT5377 is a ±100 ppb precision MEMS Super-TCXO and is suitable for use as DTO 18. SiT5377 is commercially available from SiTime Corporation, 5451 Patrick Henry Drive, Santa Clara, CA 95054, USA.

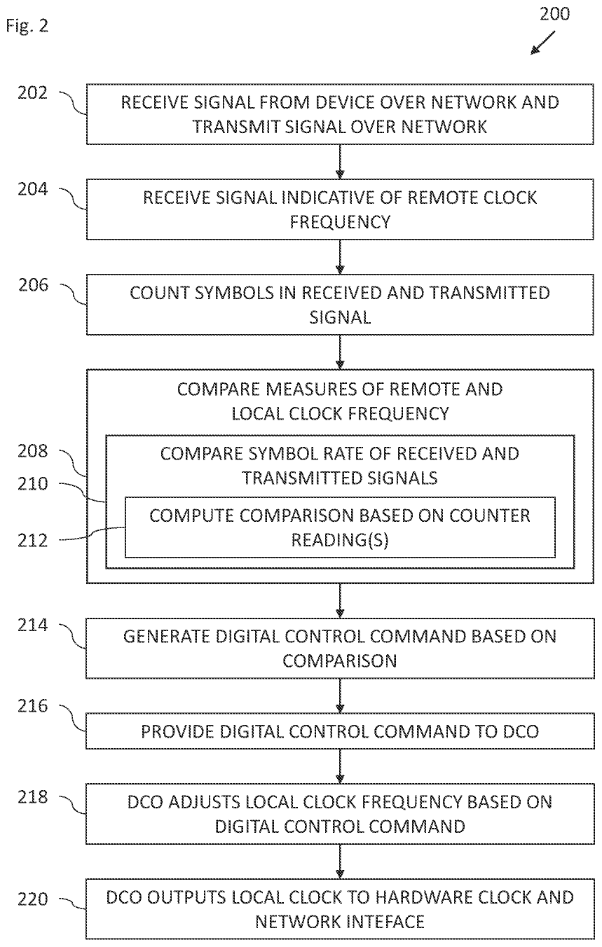

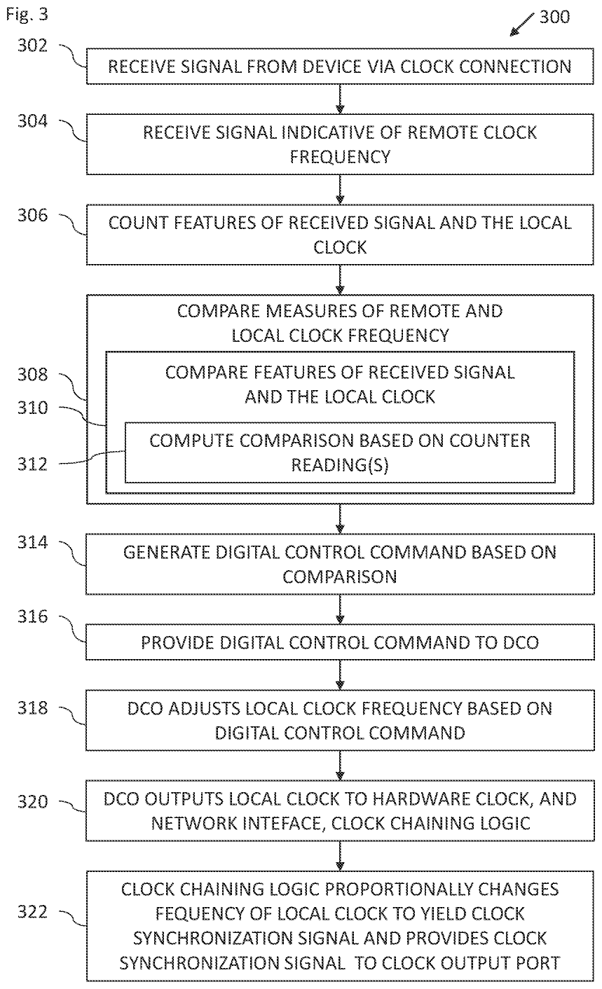

The network adapter board 14 (or each network adapter board 14) may include any one or more of the following: a core phase-locked loop (PLL) 20, clock synchronization circuitry 22, a hardware clock 24, a network interface 26, clock chaining logic 28, a firmware controller 30, a digital control channel 32, and a serializer/deserializer (SerDes) PLL 34. The network interface 26 may include one or more ports 36 to receive and/or transmit packets over a network 38 from/to one or more remote devices 40 (only one shown for the sake of simplicity). The network interface 26 may also include one or more counters 42 in which to count symbols sent and received by the ports 36 described in more detail with reference to FIG. 2. The clock chaining logic 28 may also include one or more counters 44 described in more detail with reference to FIG. 3.

The DCO 18 is connected to the hardware clock 24 via the core PLL 20. The DCO 18 is configured to output a local clock 46 towards the hardware clock 24. The hardware clock 24 is configured to maintain a time-of-day value advancing at a frequency proportional to the local clock frequency of the local clock 46 output by the DCO 18. The core PLL 20 is configured to proportionally change the local clock 46 provided by the DCO 18 to a frequency (e.g., to a higher frequency by multiplying the local clock by a given value) used by the hardware clock 24. The time-of-day value of the hardware clock 24 may be used to provide time values for timestamping performed by the network interface 26.

The time-of-day of the hardware clock 24 may be synchronized to a remote master time-of-day or using any suitable method, for example, PTP. In some cases, the hardware clock 24 may be a master clock for time-of-day for another device. The device 12 may include a pulse per second (PPS) input port 48 and a PPS output port 50 for receiving and sending time-of-day synchronization data, respectively.

The DCO 18 is connected to the network interface 26 via the SerDes PLL 34. The DCO 18 is configured to output the local clock 46 towards the network interface 26. The SerDes PLL 34 is configured to proportionally change the local clock 46 provided by the DCO 18 to a frequency (e.g., to a higher frequency by multiplying the local clock by a given value) used by the network interface 26. The ports 36 of the network interface 26 are configured to send packets over the network 38 at a symbol rate based on a frequency proportional to the local clock frequency.

In some embodiments, the network interface 26 is configured to count symbols received by one or more of the ports 36 and count symbols sent by one or more of the ports 36. Separate counters 42 may be maintained for sent and received symbols per port 36 or a combined counter may be maintained for both sent and received symbols per port 36 so that a difference between symbols sent and received in a time window is tracked by a counter per port 36, for example, by incrementing a counter for received symbols and decrementing that counter for sent symbols, or vice-versa.

The clock synchronization circuitry 22 may be implemented to include the clock chaining logic 28, the firmware controller 30, and the counters 42 of the network interface 26. The values of the counter(s) 42 and/or the counter(s) 44 are exposed to the firmware controller 30 to enable the firmware controller 30 to determine whether the local clock provided by the DCO 18 is faster or slower than a remote master clock, as described in more detail with reference to FIGS. 2 and 3. The firmware running on the firmware controller 30 is configured to generate digital control commands to control the DCO 18 and provide the digital control commands to the DCO 18 via the digital control channel 32. In some embodiments, the firmware controller 30 may be disposed on the network adapter board 14 externally to the network adapter chip(s) 16. In some embodiments, the functionality of the firmware controller 30 may be at least partially implemented using a hardware processor, and/or processor such as a CPU running suitable software in the device 12 or in a peripheral or host device.

In some situations, the remote master clock may be received from one of the remote devices 40 over the network 38. The symbol rate of the data received from that remote device 40 is counted by the network interface 26 using the counters 42. Controlling the DCO 18 based on the remote master clock being received from the remote device 40 is described in more detail with reference to FIG. 2.

In some embodiments, the device 12 may include a peripheral device communication data bus interface (e.g., PCIe interface) (not shown) in addition to, or instead of the network interface 26. The communication data bus interface may be configured to count symbols sent and received over a high-speed link disposed between the device 12 and one of the remote devices 40. The clock synchronization circuitry 22 may be configured to synchronize the local clock 46 generated by the DCO 18 to a remote master clock received from one of the remote devices 40 via the communication data bus interface.

The device 12 may also include a clock input port 56. In some situations, the clock chaining logic 28 may be configured to receive the remote master clock as a clock synchronization signal from a chained device 52 via a clock connection 54 (e.g., a clock cable or PCB trace) connected to the clock input port 56. The DCO 18 may also be connected to the clock chaining logic 28 and be configured to provide the local clock 46 to the clock chaining logic 28. Features (e.g., pulses of the signals or other identifiable sections of the signal waveform such as rising edges of the waveform) of the clock synchronization signal and local clock 46 are counted by the clock chaining logic 28 using the counters 44. As the local clock 46 and the clock synchronization signal may be at different base frequencies, for example, the local clock 46 may be around 156.25 MHz whereas the clock synchronization signal may be around 10 MHz, either the counting method of the features of the local clock 46 and the clock synchronization signal need to be adjusted, and/or the computation of the frequency difference needs to take into account the difference between the base frequencies, or some other method may be employed to equate the differences in the base frequencies. The device 12 may also include a clock output port 60. The clock chaining logic 28 may multiply or divide the local clock 46 by a given factor to yield a clock synchronization signal for output to another chained device 58 via a clock connection 62 (e.g., a clock cable or PCB trace) connected to the clock output port 60. FIG. 1 shows the chained device 52 and the chained device 58 disposed externally to the device 12. In some embodiments, the chained device 52 and/or the chained device 58 may be disposed on the (network adapter) board 14. Adjusting the DCO 18 based on the remote master clock being received from the chained device 52 is described in more detail with reference to FIG. 3.

When the device 12 includes multiple network adapter chips 16, the network interface 26 and the clock synchronization circuitry 22 may be distributed among the multiple chips 16.

In practice, some, or all of these functions of the clock synchronization circuitry 22 may be combined in a single physical component or, alternatively, implemented using multiple physical components. These physical components may comprise hard-wired or programmable devices, or a combination of the two. In some embodiments, at least some of the functions of the clock synchronization circuitry 22 may be carried out by a programmable processor under the control of suitable software. This software may be downloaded to a device in electronic form, over a network, for example. Alternatively, or additionally, the software may be stored in tangible, non-transitory computer-readable storage media, such as optical, magnetic, or electronic memory.

Reference is now made to FIG. 2, which is a flowchart 200 including steps in a method of operation of the system 10 of FIG. 1 including synchronization to a remote clock frequency received over the network 38 or other high speed communication link. Reference is also made to FIG. 1.

One of the ports 36 (designated as receiving the master clock) of the network interface 26 is configured to receive a signal including data (e.g., first packets) from the device 40 over the network 38 and transmit a signal including data (e.g., second packets) over the network 38 (block 202).

The clock synchronization circuitry 22 is configured to receive the signal from the device 40, the signal being indicative of a remote clock frequency (block 204). In some embodiments, the part of the network interface 26 included in the clock synchronization circuitry 22 is configured to receive from the device 40 the signal indicative of the remote clock frequency (block 204). The data rate, e.g., symbol rate, of the received signal is typically indicative of the remote clock frequency. The remote clock frequency is the frequency of a remote clock which is remote to the local clock 46 generated by the DCO 18. The remote clock may be external to the clock synchronization system 10. The remote clock may be internal to the clock synchronization system 10 but not generated by the DCO 18. For example, the network adapter board 14 may include another DCO which generates the remote clock for example. This latter example may be more relevant to the embodiment of FIG. 3 where the source of the remote clock is from the chained device 52 which may be external to the clock synchronization system 10 or disposed on the network adapter board 14.

In some embodiments, the part of the network interface 26 included in the clock synchronization circuitry 22 is configured to count symbols of the received signal and the transmitted signal in a time window using the counter(s) 42 (block 206). The firmware controller 30 may be configured to send a command to the network interface 26 to initiate counting of the symbols. The symbols of the received signal may be counted on one of the counters 42 and the symbols of the transmitted signal may be counted on another one of the counters 42. In some embodiments, the symbols of the received signal and the transmitted signal may be counted on the same counter 42 such that the counter 42 is incremented for every received symbol and decremented for every transmitted symbol, or vice-versa.

The clock synchronization circuitry 22 is configured to compare measures of the remote clock frequency and the local clock frequency (block 208). In some embodiments, the firmware controller 30 of the clock synchronization circuitry 22 is configured to run firmware to compute the comparison of the remote clock frequency and the local clock frequency.

In some embodiments, the clock synchronization circuitry 22 is configured to compare the symbol rate of the received signal to a symbol rate of the transmitted signal to provide the comparison of the remote clock frequency and the local clock frequency (block 210). In some embodiments, the firmware controller 30 of the clock synchronization circuitry 22 is configured to run the firmware to compute the comparison of the remote clock frequency and the local clock frequency based on the symbol count of the counter(s) 42 (block 212). For example, the comparison may be equal to the difference between the symbol count of received symbols and symbol count of the transmitted symbols in the time window.

The firmware controller 30 of the clock synchronization circuitry 22 is configured to run the firmware to generate a digital control command based on the comparison (block 214). For example, if the symbol count of received symbols is greater than symbol count of the transmitted symbols in the time window, then the remote clock is faster than the local clock and therefore the speed of the local clock should be increased, and vice-versa. The adjustment to the speed of the local clock may be proportional to the difference between the symbol count of received symbols and symbol count of the transmitted symbols in the time window.

In some embodiments, the digital control command indicates a new clock frequency to which to change the local clock frequency by the DCO 18. For example, the digital control command may take the following form: “set your frequency to your initial frequency multiplied by X/Y”, where X and Y could be any suitable values such as 100 million plus 1 and 100 million, or 100 billion plus 1 and 100 billion. The interface may also be a single number, which multiplies the initial frequency, such as 1.00000001.

In some embodiments, the digital control command indicates a frequency adjustment to be made by the DCO 18 to the local clock frequency. For example, if the current frequency of the local clock 46 is 156.25 MHz and the local clock 46 is slow by 1 Hz, the digital control command may indicate that the new clock frequency should be increased by 1 Hz.

The firmware controller 30 is configured to provide the digital control command to the DCO 18 via the digital control channel 32 (block 216). The DCO 18 is configured to adjust the local clock frequency responsively to the digital control command received from the firmware controller 30 (block 218). The DCO 18 is configured to output the local clock 46 towards the hardware clock 24 and the network interface 26 via the core PLL 20 and the SerDes PLL 34, respectively (block 220).

Reference is now made to FIG. 3, which is a flowchart 300 including steps in a method of operation of the system 10 of FIG. 1 including synchronization to a remote clock frequency received from the chained device 52. Reference is also made to FIG. 1.

The clock input port 56 is configured to receive a first clock synchronization signal via clock connection 54 from chained device 52 (block 302). The clock chaining logic 28 is configured to receive the first clock synchronization signal from the clock input port 56 (block 304). The first clock synchronization signal is indicative of the remote clock frequency of the clock running on the chained device 52. The first clock synchronization signal is generally an analogue signal having a frequency proportional to the frequency of the clock running on the chained device 52. For example, the clock running on the chained device 52 may have a frequency around 156.25 MHz, while the clock synchronization signal has a frequency around 10 MHz. The remote clock frequency is the frequency of a remote clock which is remote to local clock generated by the DCO 18. The remote clock may be external to the clock synchronization system 10. The remote clock may be internal to the clock synchronization system 10 but not generated by the DCO 18. For example, the network adapter board 14 may include chained device 52 which includes another DCO which generates the remote clock.

In some embodiments, the clock chaining logic 28 is configured to count features of the received first clock synchronization signal and the local clock 46 in a time window using the counter(s) 44 (block 306). The features may include pulses of the signals or other identifiable sections of the signal waveform, e.g., rising edges of the waveform. The firmware controller 30 may be configured to send a command to the clock chaining logic 28 to initiate counting of the features. The features of the received first clock synchronization signal may be counted on one of the counters 44 and the features of the local clock 46 may be counted on another one of the counters 44. In some embodiments, the features of the first clock synchronization signal and the local clock 46 may be counted on the same counter 42 such that the counter 44 is incremented for every feature of the first clock synchronization signal and decremented for every feature of the local clock 46 (assuming the signals have compatible frequencies), or vice-versa.

The clock synchronization circuitry 22 is configured to compare measures of the remote clock frequency and the local clock frequency (block 308). In some embodiments, the firmware controller 30 of the clock synchronization circuitry 22 is configured to run firmware to compute the comparison of the remote clock frequency and the local clock frequency. In some embodiments, the clock synchronization circuitry 22 is configured to compare a number of features of the first clock synchronization signal to a number of features of the local clock 46 to provide the comparison of the remote clock frequency and the local clock frequency (block 310). In some embodiments, the firmware controller 30 of the clock synchronization circuitry 22 is configured to run the firmware to compute the comparison of the remote clock frequency and the local clock frequency based on the count value(s) of the counter(s) 44 (block 312). For example, the comparison may be equal to the difference between the feature count of the first clock synchronization signal and the feature count of the local clock 46 in the time window.

The firmware controller 30 of the clock synchronization circuitry 22 is configured to run the firmware to generate a digital control command based on the comparison (block 314). For example, if the feature count of the first clock synchronization signal is greater than the feature count of the local clock 46 in the time window, then the remote clock (as indicated by the first clock synchronization signal) is faster than the local clock 46 and therefore the speed of the local clock 46 should be increased. The adjustment to the speed of the local clock 46 may be proportional to the difference between the feature count of the first clock synchronization signal and the feature count of the local clock 46 in the time window.

In some embodiments, the digital control command indicates a new clock frequency to which to change the local clock frequency by the DCO 18. For example, the digital control command may take the following form: “set your frequency to your initial frequency multiplied by X/Y”, where X and Y could be any suitable values such as 100 million plus 1 and 100 million, or 100 billion plus 1 and 100 billion. The interface may also be a single number, which multiplies the initial frequency, such as 1.00000001.

In some embodiments, the digital control command indicates a frequency adjustment to be made by the DCO 18 to the local clock frequency. For example, if the current frequency of the local clock 46 is 156.25 MHz and the local clock 46 is slow by 1 Hz, the digital control command may indicate that the new clock frequency should be increased by 1 Hz.

The firmware controller 30 is configured to provide the digital control command to the DCO 18 via the digital control channel 32 (block 316). The DCO 18 is configured to adjust the local clock frequency responsively to the digital control command received from the firmware controller 30 (block 318). The DCO 18 is configured to output the local clock 46 towards the hardware clock 24 and the network interface 26 via the core PLL 20 and the SerDes PLL 34, respectively (block 320).

The clock chaining logic 28 may be configured to: proportionally change (e.g., step up or step down but with a constant proportion of the base frequency of the local clock 46) a frequency of the local clock 46 to yield a second clock synchronization signal; and provide the second clock synchronization signal to the clock output port 60 for output to the chained device 58 via the clock connection 62 (clock 322). The clock output port 60 is configured to provide the second clock synchronization signal to the chained device 58 via the clock connection 62.

Various features of the invention which are, for clarity, described in the contexts of separate embodiments may also be provided in combination in a single embodiment. Conversely, various features of the invention which are, for brevity, described in the context of a single embodiment may also be provided separately or in any suitable sub-combination.

The embodiments described above are cited by way of example, and the present invention is not limited by what has been particularly shown and described hereinabove. Rather the scope of the invention includes both combinations and sub-combinations of the various features described hereinabove, as well as variations and modifications thereof which would occur to persons skilled in the art upon reading the foregoing description and which are not disclosed in the prior art.

What is claimed is:

1. A system, comprising:
a digitally controlled oscillator (DCO) to generate a local clock having a local clock frequency; and
clock synchronization circuitry to:
receive from a device a signal indicative of a remote clock frequency;
compare measures of the remote clock frequency and the local clock frequency;
generate a digital control command based on the comparison; and
provide the digital control command to the DCO, wherein the DCO is to adjust the local clock frequency responsively to the digital control command.

2. The system according to claim 1, wherein digital control command indicates a new clock frequency to which to change the local clock frequency by the DCO.

3. The system according to claim 1, wherein digital control command indicates a frequency adjustment to be made by the DCO to the local clock frequency.

4. The system according to claim 1, further comprising:
a network interface to receive the signal including first packets from the device over a network and transmit a signal including second packets over the network;
the clock synchronization circuitry is to compare a symbol rate of the received signal to a symbol rate of the transmitted signal to provide the comparison of the remote clock frequency and the local clock frequency.

5. The system according to claim 4, further comprising multiple chips, wherein the network interface and the clock synchronization circuitry are distributed among the multiple chips.

6. The system according to claim 4, wherein the clock synchronization circuitry includes at least one counter in which the clock synchronization circuitry is to count symbols of the received signal and the transmitted signal in a time window, the clock synchronization circuitry is to run firmware to compute the comparison of the remote clock frequency and the local clock frequency based on at least one symbol count of the at least one counter.

7. The system according to claim 1, further comprising a clock input port to receive the signal from the device via a clock connection, the clock synchronization circuitry is configured to compare features of the received signal and the local clock to provide the comparison of the remote clock frequency and the local clock frequency.

8. The system according to claim 7, wherein the clock synchronization circuitry includes clock chaining logic which includes at least one counter in which the clock chaining logic is to count the features of the received signal and the local clock in a time window, the clock synchronization circuitry being to run firmware to compute the comparison of the remote clock frequency and the local clock frequency based on at least one count value of the at least one counter.

9. The system according to claim 7, further comprising a clock output port to provide a clock synchronization signal to another device via another clock connection.

10. The system according to claim 9, wherein the clock chaining logic is to:
proportionally change a frequency of the local clock to yield the clock synchronization signal; and
provide the clock synchronization signal to the clock output port for output to the other device via the other clock connection.

11. The system according to claim 1, wherein clock synchronization circuitry is to run firmware to compute the comparison of the remote clock frequency and the local clock frequency.

12. The system according to claim 1, further comprising a hardware clock to maintain a time-of-day value advancing at a frequency proportional to the local clock frequency of the local clock output by the DCO, wherein the DCO is connected to the hardware clock and is to output the local clock towards the hardware clock.

13. The system according to claim 1, further comprising a network interface including ports to send packets over a network at a symbol rate based on a frequency proportional to the local clock frequency, wherein DCO is connected to the network interface and is to output the local clock towards the network interface.

14. A method, comprising:
generating a local clock having a local clock frequency with a digitally controlled oscillator (DCO);
receiving from a device a signal indicative of a remote clock frequency;
comparing measures of the remote clock frequency and the local clock frequency;
generating a digital control command based on the comparison; and
provide the digital control command to the DCO; and
adjusting the local clock frequency by the DCO responsively to the digital control command.

15. The method according to claim 14, wherein digital control command indicates a new clock frequency to which to change the local clock frequency by the DCO.

16. The method according to claim 14, wherein digital control command indicates a frequency adjustment to be made by the DCO to the local clock frequency.

17. The method according to claim 14, wherein:
the receiving includes receiving the signal including first packets from the device over a network, the method further comprising transmitting a signal including second packets over the network;
the comparing includes comparing a symbol rate of the received signal to a symbol rate of the transmitted signal to provide the comparison of the remote clock frequency and the local clock frequency.

18. The method according to claim 17, further comprising:
counting symbols of the received signal and the transmitted signal in a time window using at least one counter; and
running firmware to compute the comparison of the remote clock frequency and the local clock frequency based on at least one symbol count of the at least one counter.

19. The method according to claim 14, wherein:
the receiving includes receiving the signal from the device via a clock connection; and
the comparing includes comparing features of the received signal and the local clock to provide the comparison of the remote clock frequency and the local clock frequency.

20. The method according to claim 19, further comprising:
counting the features of the received signal and the local clock in a time window using at least one counter; and
running firmware to compute the comparison of the remote clock frequency and the local clock frequency based on at least one count value of the at least one counter.

21. The method according to claim 19, further comprising providing a clock synchronization signal to another device via another clock connection.

22. The method according to claim 21, further comprising proportionally changing a frequency of the local clock to yield the clock synchronization signal.

23. The method according to claim 14, further comprising running firmware to compute the comparison of the remote clock frequency and the local clock frequency.

24. The method according to claim 14, further comprising maintaining a time-of-day value advancing at a frequency proportional to the local clock frequency of the local clock output by the DCO.

25. The method according to claim 14, further comprising sending packets over a network at a symbol rate based on a frequency proportional to the local clock frequency of the local clock output by the DCO.
